(19) United States
(12) Patent Application Publication
(10) Pub. No.: US 2014/0253099 A1
(43) Pub. Date: Sep. 11, 2014

(54) SEMICONDUCTOR DEVICE ON DEVICE INTERFACE BOARD AND TEST SYSTEM USING THE SAME

(71) Applicant: Samsung Electronics Co., Ltd., Suwon-si (KR)

(72) Inventors: Sang-Kyeong HAN, Daejeon (KR); Jong-Woon YOO, Gwangmyeong-si (KR); Ung-Jin JANG, Daejeon (KR)

(73) Assignee: SAMSUNG ELECTRONICS CO., LTD., Suwon-Si (KR)

(21) Appl. No.: 14/198,812

(22) Filed: Mar. 6, 2014

(30) Foreign Application Priority Data
Mar. 11, 2013 (KR) 10-2013-0025529

(51) Int. Cl. G01R 1/067; G01R 19/00

(52) U.S. Cl. CPC G01R 1/067; G01R 19/00
USPC 324/126

(57) ABSTRACT

A semiconductor device, which is mounted on a device interface board to interface an electrical measuring signal between automated test equipment (ATE) and a device under test (DUT), includes an AC test unit, a DC test unit, a first input/output (I/O) interface unit, and a second I/O interface unit. The AC test unit tests an AC characteristic of the DUT. The DC test unit provides a DC test path according to attributes of I/O terminals of the DUT. The first I/O interface unit selectively connects the AC test unit or the DC test unit to the ATE in response to a mode control signal. The second I/O interface unit selectively connects the AC test unit or the DC test unit to the DUT in response to the mode control signal.

### CROSS-REFERENCE TO RELATED APPLICATION

This application claims priority under 35 USC §119 to Korean Patent Application No. 10-2013-0025529 filed on Mar. 11, 2013 in the Korean Intellectual Property Office (KIPO), the entire disclosure of which is incorporated herein by reference.

### BACKGROUND

1. Field

Example embodiments relate to test systems. More particularly, example embodiments relate to semiconductor devices mounted on a DIB (device interface board), which provides interconnection between an ATE (Automatic Test Equipment) and a DUT (device under test), and/or test systems using the same.

2. Description of the Related Art

As semiconductor devices evolve toward the direction of higher speed, higher performance and higher integration, various types of semiconductor devices are being developed. As such, a circuit configuration of a PCB of a test interface board providing electrical connected between an ATE and a DUT becomes complicated.

Accordingly, Universal test interface boards, which are applicable to various DUTs regardless of types of DUTs, are being researched.

The universal test interface board may include an active device, for example, an ASIC or an FPGA, which is capable of programming a topology according to types of DUTs. The active device may provide a test pattern for testing, e.g., an AC margin associated with a transmission delay time, a set-up time, and a hold time of a signal to the DUT, receive an output signal from the DUT, and compare the output signal with an expected value to determine pass/fail.

However, the active device uses input/output buffers for signal characteristics in a device. Accordingly, a direct current (DC) test may not be achieved through the active device using the input/output buffers.

### SUMMARY

Example embodiments provide a semiconductor device on a DIB capable of improving test operation efficiency by testing an AC (alternating current) and a DC on one board without exchanging hardware and a test system using the same.

According to an example embodiment, a semiconductor device mounted on a device interface board to interface an electrical measuring signal between automated test equipment (ATE) and a device under test (DUT), includes an AC test unit, a DC test unit, a first input/output (I/O) interface unit, and a second I/O interface unit. The AC test unit tests an AC characteristic of the DUT. The DC test unit provides a DC test path according to attributes of I/O terminals of the DUT. The first I/O interface unit selectively connects the AC test unit or the DC test unit to the ATE in response to a mode control signal. The second I/O interface unit selectively connects the AC test unit or the DC test unit to the DUT in response to the mode control signal.

In an embodiment, the AC test unit may include an AC test logic unit, a first buffer unit that buffers a signal between the first I/O interface unit and the AC test logic unit, and a second buffer unit that buffers a signal between the second I/O interface unit and the AC test logic unit.

The AC test logic unit may include a built off self-test (BOST) logic.

In an embodiment, the DC test unit may include a routing controller that generates a routing control signal according to attributes of an input/output terminal of the DUT, and a switch matrix that switches a connection path of signal lines of the first I/O interface unit and the second I/O interface unit in response to the routing control signals.

The semiconductor device may be configured by one of an FPGA chip and ASIC chip.

The routing control signals may include first and second routing control signals.

The DC test path may have an equilibrium state when the first routing control signal is at a high level and the second routing control signal is at a low level.

The DC test path may have a cross state when the first routing control signal is at a low level and the second routing control signal is at a high level.

According to an example embodiment, a test system includes automated test equipment (ATE), and a device interface board. The device interface board interfaces an electrical measuring signal between the ATE and a device under test (DUT). The device interface board includes a built off self-test (BOST) board, and a socket board. The BOST board includes a BOST semiconductor device that selectively performs one of an AC test and a DC test.

In an embodiment, the BOST semiconductor device may include a programmable switch matrix that provides (e.g., programs) a DC test path according to an attribute of an input/output (I/O) terminal of the DUT.

The programmable switch matrix may include a routing controller that generates routing control signals according to an attribute of the input/output terminal of the DUT, and a switch matrix that switches a connection path for connecting DC input/output signals of the ATE to I/O terminals of the DUT in response to the routing control signals.

In an embodiment, the socket board may include at least one socket and at least one test module corresponding to the at least one socket.

The at least one socket may constitute at least one test site and the ATE controls the at least one test sites in a multi-test site scheme.

The routing controller may download DC test path program data through one of the ATE and an external computer.

The test module may have a loop-back test function.

According to an example embodiment, a semiconductor device mounted on a device interface board to interface an electrical testing signal between automated test equipment (ATE) and a device under test (DUT), the semiconductor device includes a first type test unit having a logic unit, the logic unit configured to test a characteristic of a first type of the DUT, a second type test unit configured to provide a test path of a second type according to attributes of input/output(I/O) terminals of the DUT, and a test interface structure configured to selectively connect the AC test unit or the DC test unit to the ATE based on a mode control signal.

The first type test unit further may include at least one I/O buffer. The logic unit may be configured to transmit and receive one of a relatively high speed signal and a relatively low speed signal to and from the DUT through the I/O buffer.

The second type test unit may include a switch matrix, and a routing controller configured to provide the test path of the second type according to the attributes of I/O terminals of the DUT.

The semiconductor device may further include a mode control signal generator configured to generate the mode control signal.

The first type may be AC and the second type may be DC.

Accordingly, because the semiconductor device described above according to example embodiments may program a topology for testing the AC and the DC on the interface board, an additional hardware block for the DC test required in a conventional semiconductor device can be omitted. Further, the DC test can be performed with respect to a new product or a modified semiconductor product without replacing the semiconductor device.

### BRIEF DESCRIPTION OF THE DRAWINGS

The above and other features of the present inventive concepts will become apparent to those of ordinary skill in the art by describing in detail example embodiments thereof with reference to the attached drawings in which:

FIG. 1 is a block diagram to illustrating a semiconductor test system according to an example embodiment.

FIG. 2 is a block diagram illustrating the DIB shown in FIG. 1 according to an example embodiment.

FIG. 3 is a circuit diagram illustrating a 2-input 2-output arrangement of a switch matrix shown in FIG. 2.

FIG. 4 is a flowchart to explain a test mode operation of a built off self-test (BOST) chip to be subject to a DC test according to an example embodiment.

### DETAILED DESCRIPTION

Various example embodiments will be described more fully hereinafter with reference to the accompanying drawings, in which some example embodiments are shown. This inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the inventive concepts. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the inventive concepts. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other.

Unless otherwise defined, all terms (including technical and scientific terms) used herein have the same meaning as commonly understood by one of ordinary skill in the art to which these inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, some example embodiments will be described in detail with reference to accompanying drawings. The same reference numerals will be assigned to the same elements, and the details thereof will be omitted in order to avoid redundancy.

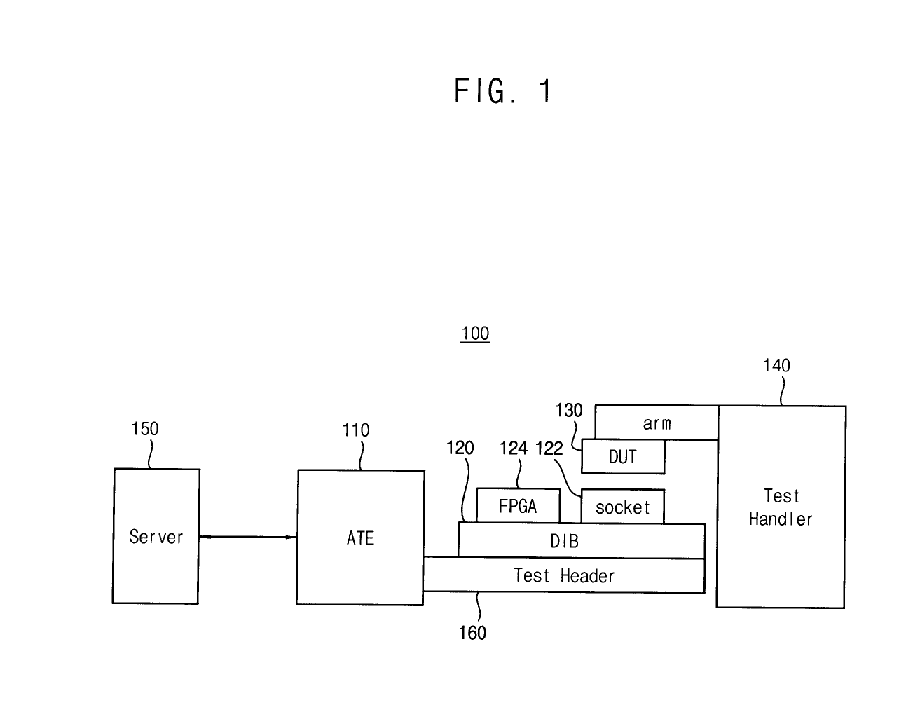

FIG. 1 is a block diagram to illustrating a semiconductor test system according to an example embodiment.

Referring to FIG. 1, the semiconductor test system 100 mainly includes an ATE (auto test equipment) 110, a DIB (device interface board) 120, a DUT (device under test) 130, and a test handler 140.

The ATE 110 is equipment that automatically tests the DUT 130, and may include, for example, a microcomputer or a microprocessor based system. The ATE 110 is electrically connected to the DIB 120 through a test header 160. The ATE 110 is electrically connected to the DUT 130 through the DIB 120, inputs a test pattern to the DUT 130 and compares an output of the DUT 130 with an expected value to determine an error of the DUT 130. The DUT 130 is mounted in a socket 122 of the DIB 120 so that the DUT 130 is electrically connected to the DIB 120. The ATE 110 may perform a DC test to test whether DC parameters of the DUT 130 are suitable for a digitalized operation of a circuit, and an AC margin test associated with a transmission delay time, a set-up time, and/or a hold time of a signal.

Further, the ATE 110 may access an external server 150 through, for example, a PCI interface. The server 150 may provide a desired (or alternatively, predetermined) user interface to provide an environment allowing a user to create a test program suitable for characteristics of a DUT 130 to be tested. Further, the server 150 may provide a user interface to transmit the test program to the ATE 110 and to receive a test result from the ATE 110 to analyze the test result. The server 150 may be a processing device, e.g., a personal computer, a desk top device, a portable device, a microprocessor, a microprocessor based or programmable consumer electronic device, a mini-computer, a main frame computer, and/or a personal mobile computing device, but example embodiments are not limited thereto.

The DUT 130 may be a volatile memory device, e.g., SRAM, DRAM or SDRAM, a non-volatile memory device (e.g., ROM, PROM, EPROM, EEPROM, flash memory, PRAM, MRAM, RRAM or FRAM), or a memory component including the volatile memory device or nonvolatile memory device. Further, the DUT 130 is not limited to a memory device or a memory package. For example, the DUT 130 may include, e.g., a memory module including a plurality of memory components, a memory card, or a memory stick. Further, the DUT 130 may include chips, e.g., an ISP (image signal processor) and a DSP (digital signal processor), which may or may not have a memory device therein.

The test handler 140 may automatically supply the DUT 130 to the ATE 110 for test. When a test process is completed, the test handler 140 may deliver the DUT 130 to a suitable location according to a test result of the ATE 110. The test handler 140 and the ATE 110 may be coupled in one-to-one or N-to-one correspondence. In general, the test handler 140 may include, for example, a loading unit, an input stage, a test site, a shuttle, an unloading unit, an output stage, and sensors.

The DIB 120 may be a printed board which is provided therein with a plurality of conductive patterns to electrically connect the ATE 110 to the DUT 130. The conductive patterns may include, for example, input/output test signal lines, clock signal lines, and power lines. The DIB 120 may include a test board or a HiFIX (high fidelity tester access fixture).

The DIB 120 may include the socket 122 and an FPGA (field programmable gate array) 124.

The FPGA 124 may be a BOST (built off self-test) chip, and may include, for example, a system channel extension, a drive, a comparator, and a power channel control block. Further, the FPGA 124 may convert a relatively low speed clock (e.g., a clock lower than 1 Gbps) and a relatively low speed test pattern into a relatively high speed clock (e.g., a clock of a few Gbps) and a relatively high speed test pattern, and apply the relatively high speed clock and the relatively high speed test pattern to an input pin of the DUT 120. The FPGA 124 may be used to replace the ATE having low performance. Further, the FPGA 124 may be used to perform substantially the same function as a BIST (built in self-test).

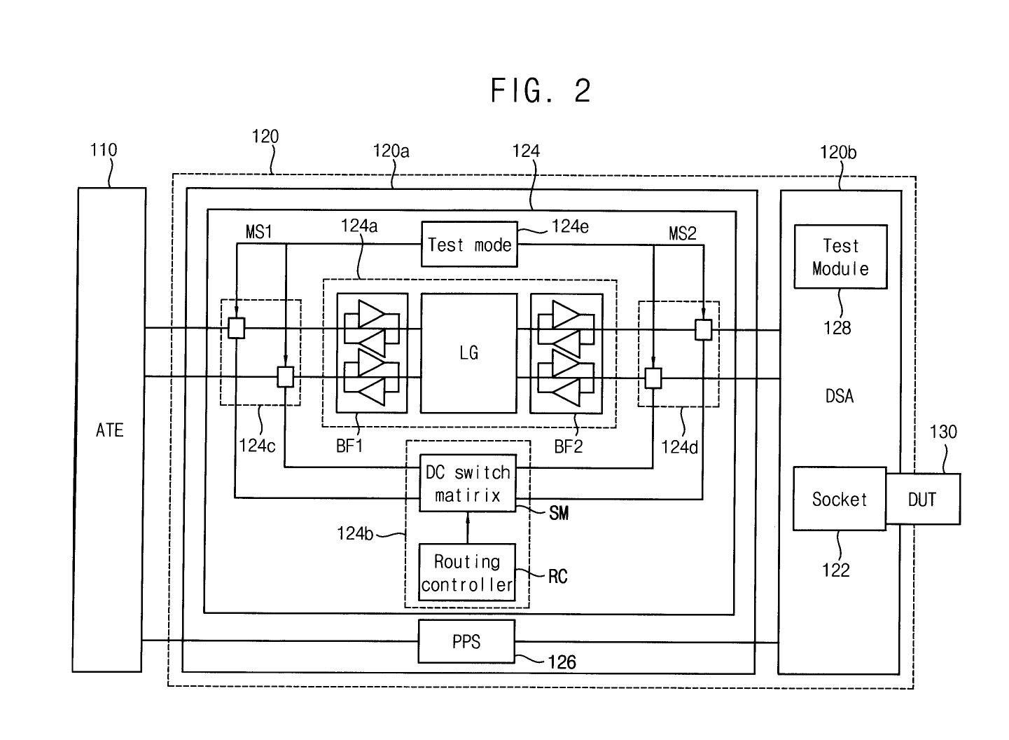

FIG. 2 is a block diagram illustrating the DIB shown in FIG. 1 according to an example embodiment.

Referring to FIG. 2, the DIB 120 includes a BOST board 120a and a socket board 120b. The BOST board 120a may include a BOST chip 124 implemented, for example, with an FPGA chip or an ASIC chip and a PPS (Programmable Power Supply) block 126. The socket board 120b may be a device specific adaptor (DSA) and may be designed according to a type of the DUT 130. When a type of the DUT 130 changes, the socket board 120b may be replaced with a socked board corresponding to the changed type of the DUT 130. Further, the socket board 120b may include at least one test module 128.

The BOST chip 124 may include, for example, an AC test unit 124a, a DC test unit 124b, a first input/output (I/O) interface unit 124c, a second I/O interface unit 124d, and a mode control signal generating unit 124e.

The AC test unit 124a may include a logic unit LG that tests AC characteristics of the DUT 130 and I/O buffers BF1 and BF2. The logic unit LG may transmit and receive a relatively low speed signal to and from the I/O buffer BF1. The relatively low speed signal may include, for example, a test command, an address, data, and an ATE clock signal. The logic unit LG may transmit and receive a relatively high speed signal to and from the DUT 130 through the I/O buffer BF2. The relatively high speed signal may include, for example, a DUT test clock signal, a test pattern, and a test result signal. The logic unit LG may include, for example, a command interpreter, a driver, a comparator, a test pattern generator, an expected value generator, a control block, and a memory. Because the AC test unit 124a outputs and receives an AC signal to and from the outside through the I/O buffers BF1 and BF2 to stabilize input/output signals, the AC test unit 124a may not receive or output a DC signal. Accordingly, the DC test may not be performed in a conventional BOST chip, which includes the AC test unit 124a, but does not include a DC test unit.

The DC test unit 124b may include, for example, a DC switch matrix SM and a routing controller RC, which programs a DC test path according to attributes of I/O terminals of the DUT 130. The DC test path may be programmed in the switch matrix SM by the routing controller RC. Accordingly, ATE DC test signals may be electrically supplied in match with the input/output terminals of the DUT 130. Therefore, even when a type of the DUT 130 changes, the DC test may be possible without changing the BOST board 120a, thereby reducing the test cost. The routing controller RC may download a routing program from, for example, the ATE 110 or an external computer to program a DC test path. Although it has been described that the DC test unit 124b may include the switch SM and the routing controller RC, example embodiments are not limited thereto. For example, the DC test unit 124b may be configured by one programmable switch matrix.

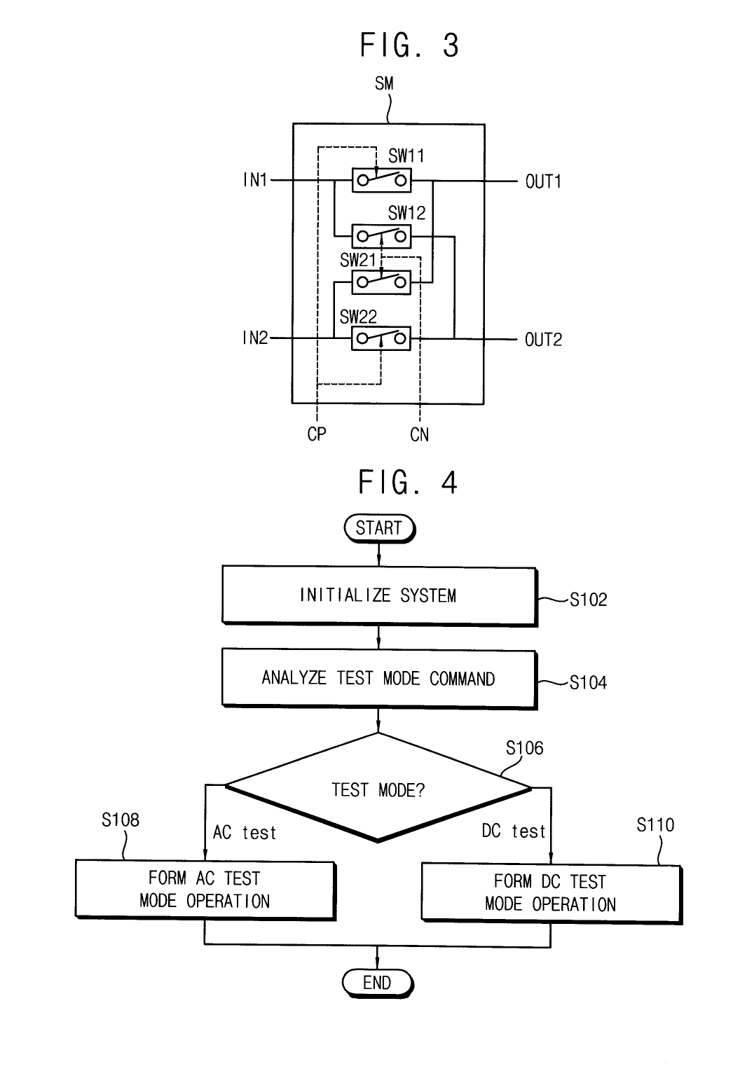

FIG. 3 is a circuit diagram illustrating a 2-input 2-output arrangement of a switch matrix SM shown in FIG. 2. The switch matrix SM is not limited to the 2-input 2-output arrangement, but may have an M-input N-output arrangement.

Referring to FIG. 3, a switch SW11 is connected between an input IN1 and an output OUT1. A switch SW12 may be connected between the input N1 and an output OUT2. A switch SW21 may be connected between an input IN2 and the output OUT1. A switch SW22 may be connected between the input IN2 and the output OUT2. The switch SW11 and the switch SW22 may be switched in response to a first routing control signal CP. The switch SW12 and the switch SW21 may be switched in response to a second routing control signal CN. The first routing control signal CP and the second routing control signal CN may be provided from the routing controller RC.

Accordingly, if the routing control signal CP has a high level and the routing control signal CN has a low level, switches SW11 and SW22 may be turned-on, but the switches SW12 and SW21 may be turned-off. Thus, a DC test path having an equilibrium state (e.g., IN1-OUT1 and IN2-OUT2) may be formed. In contrast, if the routing control signal CP has the low level and the routing control signal CN has the high level, switches SW11 and SW22 may be turned-off, but the switches SW12 and SW21 may be turned-on. Thus, a DC test path having a cross state (e.g., IN1-OUT2 and IN2-OUT1) may be formed.

In FIG. 2, a first I/O interface unit 124c and a second I/O interface unit 124d selectively switch I/O signals in response to first and second mode control signals MS1 and MS2 generated by a mode control signal generator unit 124e.

The first input/output interface unit 124c may refer to a backplane interface unit, and may selectively connect the AC text unit 124a or the DC test unit 124b to the ATE 110 in response to a first mode control signal MS1.

The second I/O interface unit 124d may refer to a drive board interface unit, and may selectively connect the AC test unit 124a or the DC test unit 124b to the DUT 130 in response to a second mode control signal MS2. The second I/O interface unit 124d may include at least one resistor for impedance matching.

The socket board 120b is also called a drive board or a load board. The socket board 120b may include at least one socket 122, in which at least one DUT 130 may be mounted for a parallel test, and the sockets 122 may be tested in a test site having a multi-site scheme. According to the multi-site scheme, loading and sorting of the DUT may be possible in other sites while testing is being conducted in one site. Thus, the test efficiency can be improved.

Further, a test module 128 of the socket board 120b may be detachably mounted to the socket board 120b in the form of a card. The test module 128 may be prepared in the form of, for example, a passive card or an active card. The test module 128 may enable a loopback test where a test output of the DUT 130 is fed back to the DUT 130 as an input.

FIG. 4 is a flowchart illustrating a test mode operation of a built off self-test (BOST) chip to be subject to a DC test according to an example embodiment.

Referring to FIG. 4, the BOST chip 124 initializes a system (S102) and interprets a test mode command provided from the ATE 110 (S104). The BOST chip 124 may determines whether the test mode command interpreted in step S104 is an AC test mode or a DC test mode (S106). When the interpreted test mode command is the AC test mode in step S106, the first and second mode control signals MS1 and MS2 generated from the mode control signal generator 124e may be maintained in an inactive state (e.g., a low state). Accordingly, the first input interface unit 124c and the second input interface unit 124d may form an AC test operation mode to connect the ATE 110—the AC test unit 124a—the socket board 120b—the DUT 130 (S108).

When the interpreted test mode command is the AC test mode in step S106, the first and second mode control signals MS1 and MS2 generated from the mode control signal generator 124e may be maintained in an active state (e.g., a high state). Accordingly, the first I/O interface unit 124c and the second I/O interface unit 124d may form a DC test operation mode to connect the ATE 110—the DC test unit 124b—the socket board 120b—the DUT 130 (5110).

As described above, the example embodiments can solve the restriction of the DC test in a conventional BOST chip having input/output buffers. By forming a bypass for a DC, the DC response restriction caused by the change in attribute of a ball in the conventional BOST chip can be solved. Routing of the switch matrix may be controlled by the routing controller provided in an ASIC. Even when a device package size and a ball attribute of the DUT changes, a DC test may be possible by resetting a test path through the DC switch matrix.

Because example embodiments include a DC programmable switching matrix in the BOST chip mounted on the DIB of the test system, a DC programmable test path may be formed between the ATE and the DUT. Accordingly, the DC test, which cannot be performed in a conventional BOST test scheme, can be performed without providing additional hardware for the DC test. The DC test may be possible with respect to a new product or a modified product without providing a new board by solving a physical routing restriction. Accordingly, the test cost can be reduced.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device mounted on a device interface board to interface an electrical measuring signal between automated test equipment (ATE) and a device under test (DUT), the semiconductor device comprising:
an AC test unit configured to test an AC characteristic of the DUT;
a DC test unit configured to provide a DC test path according to attributes of input/output (I/O) terminals of the DUT;
a first I/O interface unit configured to selectively connect the AC test unit or the DC test unit to the ATE in response to a mode control signal; and
a second I/O interface unit configured to selectively connect the AC test unit or the DC test unit to the DUT in response to the mode control signal.

2. The semiconductor device of claim 1, wherein the AC test unit comprises:
an AC test logic unit;
a first buffer unit configured to buffer a signal between the first I/O interface unit and the AC test logic unit; and
a second buffer unit configured to buffer a signal between the second I/O interface unit and the AC test logic unit.

3. The semiconductor device of claim 2, wherein the AC test logic unit comprises a built off self-test (BOST) logic.

4. The semiconductor device of claim 1, wherein the DC test unit comprises:
a routing controller configured to generate routing control signals according to attributes of an input/output terminal of the DUT; and
a switch matrix configured to switch a connection path of signal lines of the first I/O interface unit and the second I/O interface unit in response to the routing control signals.

5. The semiconductor device of claim 4, wherein the semiconductor device is configured by one of an FPGA chip and ASIC chip.

6. The semiconductor device of claim 4, wherein the routing control signals include first and second routing control signals.

7. The semiconductor device of claim 6, wherein the DC test path has an equilibrium state when the first routing control signal is at a high level and the second routing control signal is at a low level.

8. The semiconductor device of claim 6, wherein the DC test path has a cross state when the first routing control signal is at a low level and the second routing control signal is at a high level.

9. A test system comprising:
automated test equipment (ATE); and
a device interface board configured to interface an electrical measuring signal between the ATE and a device under test (DUT),
wherein the device interface board includes,
a built off self-test (BOST) board including a BOST semiconductor device, the BOST semiconductor device configured to selectively perform one of an AC test and a DC test; and
a socket board.

10. The test system of claim 9, wherein the BOST semiconductor device comprises:
a programmable switch matrix configured to provide a DC test path according to an attribute of an input/output (I/O) terminal of the DUT.

11. The test system of claim 10, wherein the programmable switch matrix comprises:
a routing controller configured to generate routing control signals according to an attribute of the input/output terminal of the DUT; and
a switch matrix configured to switch a connection path for connecting DC input/output signals of the ATE to I/O terminals of the DUT in response to the routing control signals.

12. The test system of claim 9, wherein the socket board comprises:
at least one socket; and
at least one test module corresponding to the at least one socket.

13. The test system of claim 12, wherein the at least one socket constitutes at least one test site and the ATE controls the at least one test sites in a multi-test site scheme.

14. The test system of claim 11, wherein the routing controller downloads DC test path program data through one of the ATE and an external computer.

15. The test system of claim 12, wherein the test module has a loop-back test function.

16. A semiconductor device mounted on a device interface board to interface an electrical testing signal between automated test equipment (ATE) and a device under test (DUT), the semiconductor device comprising:
a first type test unit having a logic unit, the logic unit configured to test a characteristic of a first type of the DUT;
a second type test unit configured to provide a test path of a second type according to attributes of input/output(I/O) terminals of the DUT; and
a test interface structure configured to selectively connect one of the first type test unit and the second type test unit to the ATE based on a mode control signal.

17. The semiconductor device of claim 16, wherein the first type test unit further comprises:
at least one I/O buffer, the logic unit configured to transmit and receive one of a relatively high speed signal and a relatively low speed signal to and from the DUT through the I/O buffer.

18. The semiconductor device of claim 16, wherein the second type test unit comprises:
a switch matrix; and
a routing controller configured to provide the test path of the second type according to the attributes of I/O terminals of the DUT.

19. The semiconductor device of claim 16, further comprising:
a mode control signal generator configured to generate the mode control signal.

20. The semiconductor device of claim 16, wherein the first type is AC and the second type is DC.
